(19) United States
(12) Patent Application Publication
(10) Pub. No.: US 2019/0296730 A1
(43) Pub. Date: Sep. 26, 2019

(54) SEMICONDUCTOR DEVICE AND POWER CONVERTOR

(71) Applicants: Kabushiki Kaisha Toshiba, Tokyo (JP); Toshiba Electronic Devices & Storage Corporation, Tokyo (JP)

(72) Inventors: Tsuneo Ogura, Kamakura Kanagawa (JP); Tomoko Matsudai, Shibuya Tokyo (JP); Yoko Iwakaji, Meguro Tokyo (JP)

(21) Appl. No.: 16/137,854

(22) Filed: Sep. 21, 2018

(30) Foreign Application Priority Data
Mar. 23, 2018 (JP) 2018-055446

(51) Int. Cl. H03K 17/082; H03K 17/785; H02M 1/08; H02M 3/158; H02M 3/08

(52) U.S. Cl. CPC H03K 17/0828; H03K 17/785; H02M 3/08; H02M 3/158; H02M 1/08

(57) ABSTRACT

A semiconductor device according to an embodiment includes a transistor including a first electrode, a second electrode, and a first gate electrode; a first detector detecting a change in a first parameter of the transistor over time to acquire first temporal change data; and a first storage storing the first temporal change data.

### CROSS-REFERENCE TO RELATED APPLICATION

This application is based upon and claims the benefit of priority from Japanese Patent Application No. 2018-055446, filed on Mar. 23, 2018, the entire contents of which are incorporated herein by reference.

### FIELD

Embodiments described herein relate generally to semiconductor devices and power convertors.

### BACKGROUND

In some cases, a power transistor included in a power convertor is broken during operation. It is considered that the destruction of the power transistor is caused by some factors such as a surge voltage during a turn-off operation and a short circuit caused by erroneous ignition.

In a case in which destruction occurs in the power transistor, it is difficult to determine the cause of the destruction after the fact. It is preferable to easily determine the cause of the destruction of the power transistor in order to clarify the cause of the destruction of the power transistor and to achieve a power convertor with high reliability. In addition, it may be necessary to detect an error during the operation of the power transistor and to reflect the detection result in the control of the power transistor.

### BRIEF DESCRIPTION OF THE DRAWINGS

FIG. 1 is a diagram schematically illustrating a semiconductor device according to a first embodiment;

FIG. 2 is a circuit diagram illustrating a power convertor according to the first embodiment;

FIG. 3 is a cross-sectional view schematically illustrating a transistor according to the first embodiment;

FIGS. 4A and 4B are diagrams illustrating the function and effect of the semiconductor device according to the first embodiment;

FIG. 5 is a diagram schematically illustrating a semiconductor device according to a second embodiment;

FIG. 6 is a diagram schematically illustrating a semiconductor device according to a third embodiment;

FIG. 7 is a diagram schematically illustrating a semiconductor device according to a fourth embodiment;

FIG. 8 is a diagram schematically illustrating a semiconductor device according to a fifth embodiment;

FIG. 9 is a diagram schematically illustrating a semiconductor device according to a sixth embodiment;

FIGS. 10A and 10B are cross-sectional views schematically illustrating a transistor according to the sixth embodiment;

FIG. 11 is a diagram schematically illustrating a semiconductor device according to a seventh embodiment;

FIG. 12 is a diagram schematically illustrating a semiconductor device according to an eighth embodiment;

FIG. 13 is a diagram schematically illustrating a semiconductor device according to a ninth embodiment; and

FIG. 14 is a diagram schematically illustrating a semiconductor device according to a tenth embodiment.

### DETAILED DESCRIPTION

A semiconductor device according to an embodiment includes: a transistor including a first electrode, a second electrode, and a first gate electrode; a first detector detecting a change in a first parameter of the transistor over time to acquire first temporal change data; and a first storage storing the first temporal change data.

Hereinafter, embodiments of the invention will be described with reference to the drawings. In the following description, for example, the same members or similar members are denoted by the same reference numerals and the description of the members that have been described once will not be repeated.

In the specification, the concept of a semiconductor device includes a semiconductor chip into which a plurality of functions are integrated, an electronic circuit board on which a plurality of electronic components are arranged, or a power module obtained by integrating a plurality of electronic components into one package.

In the specification, it is assumed that a “voltage” means a potential difference from the ground potential unless otherwise defined.

### FIRST EMBODIMENT

A semiconductor device according to a first embodiment includes: a transistor including a first electrode, a second electrode, and a first gate electrode; a first detector detecting a change in a first parameter of the transistor over time to acquire first temporal change data; and a first storage storing the first temporal change data.

A power convertor according to the first embodiment includes the semiconductor device.

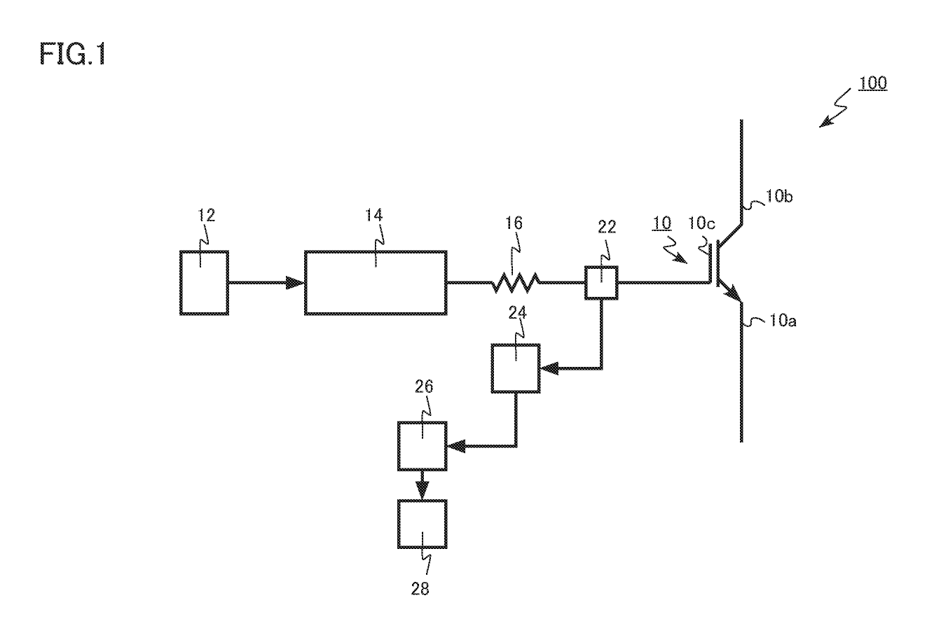

FIG. 1 is a diagram schematically illustrating the semiconductor device according to the first embodiment. The semiconductor device according to the first embodiment is a transistor circuit 100.

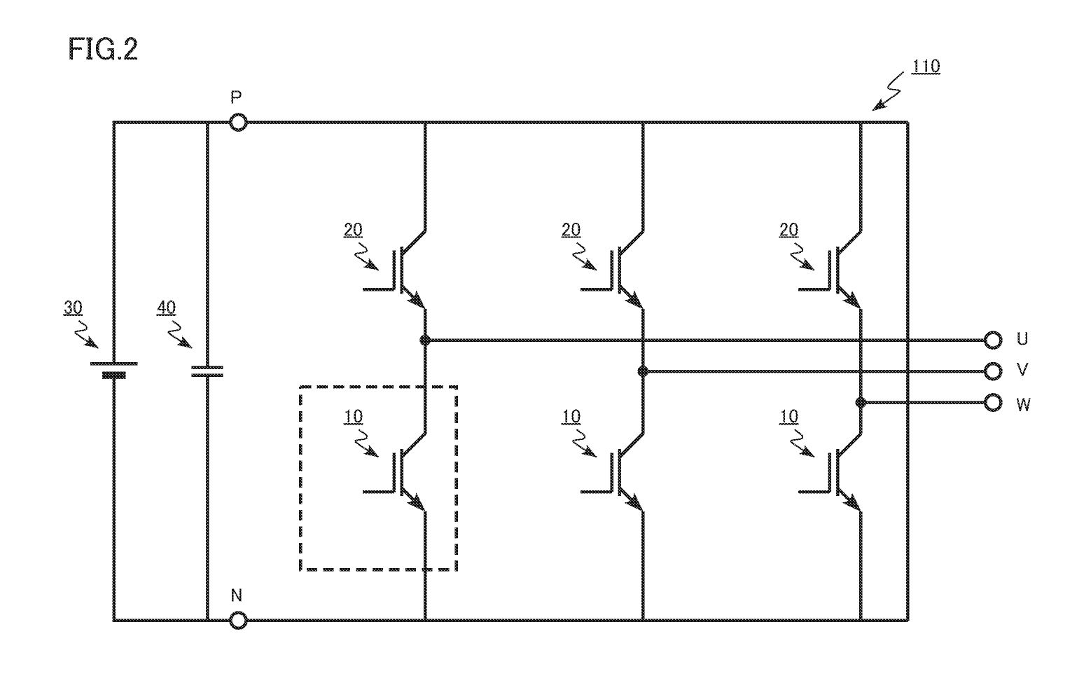

FIG. 2 is a circuit diagram illustrating the power convertor according to the first embodiment. The power convertor according to the first embodiment is an inverter circuit 110. FIG. 1 is a diagram schematically illustrating the details of the transistor circuit 100 which is a portion of the inverter circuit 110 illustrated in FIG. 2.

The inverter circuit 110 illustrated in FIG. 2 includes three sets of low-side transistors 10 and high-side transistors 20. The inverter circuit illustrated in FIG. 2 includes a positive terminal P, a negative terminal N, an output terminal U, an output terminal V, and an output terminal W. The low-side transistor 10 is an example of a transistor.

The positive terminal P is connected to a positive electrode of a direct-current power supply 30 and the negative terminal N is connected to a negative electrode of the direct-current power supply 30. For example, a smoothing capacitor 40 is provided in parallel to the direct-current power supply 30 between the positive terminal P and the negative terminal N. The inverter circuit is a three-phase inverter.

The voltage of the direct-current power supply 30 is, for example, equal to or greater than 200 V and equal to or less than 1500 V.

FIG. 1 is a diagram schematically illustrating the details of the transistor circuit 100 including one low-side transistor 10 in the inverter circuit illustrated in FIG. 2. FIG. 1 is a diagram schematically illustrating a region surrounded by a dotted line in FIG. 2.

The transistor circuit 100 according to the first embodiment includes the low-side transistor 10 (transistor), a gate pulse generation circuit 12, a gate driving circuit 14, a gate resistor 16, a voltage detector 22 (first detector), an analog-digital convertor 24, a first storage 26, and an interface 28.

The low-side transistor 10 includes an emitter electrode 10a (first electrode), a collector electrode 10b (second electrode), and a gate electrode 10c (first gate electrode). Hereinafter, the low-side transistor 10 is simply referred to as a transistor 10.

The transistor 10 is, for example, a vertical insulated gate bipolar transistor (IGBT). For example, a free-wheeling diode (not illustrated) is connected in parallel to the transistor 10.

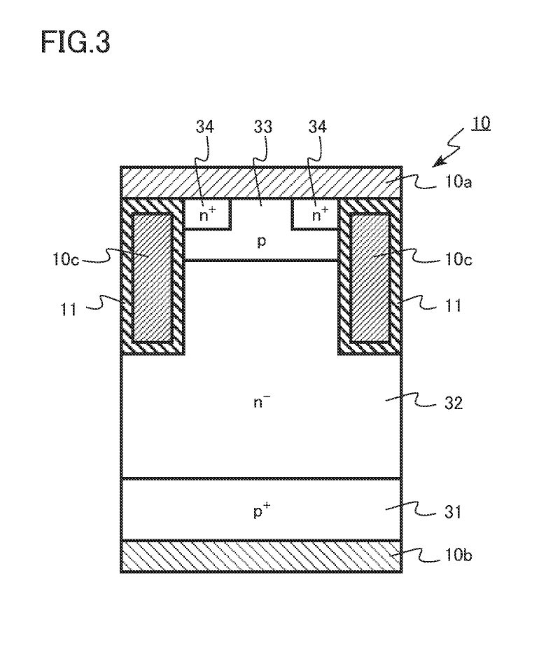

FIG. 3 is a cross-sectional view schematically illustrating the transistor 10 according to the first embodiment. The transistor 10 includes the emitter electrode 10a, the collector electrode 10b, the gate electrode 10c, a gate insulating film 11, a p⁺ collector region 31, an n⁻ drift region 32, a p-type base region 33, and an n⁺ emitter region 34. The p⁺ collector region 31, the n⁻ drift region 32, the p-type base region 33, and the n⁺ emitter region 34 are formed in, for example, a single-crystal silicon layer or a single-crystal silicon carbide layer.

The gate pulse generation circuit 12 has a function of generating a gate signal for controlling a turn-on operation and a turn-off operation of the transistor 10. The gate signal is, for example, a pulse signal.

The gate driving circuit 14 has a function of generating a gate voltage to be applied to the gate electrode 10c on the basis of the gate signal to control the driving of the transistor 10. For example, in the case of an n channel, the gate voltage changes in the range of 0 V to 15 V. Alternatively, the gate voltage changes in the range of 15 V from a negative bias.

The gate resistor 16 is provided between the gate driving circuit 14 and the gate electrode 10c. For example, the gate resistor 16 is provided between the gate driving circuit 14 and a to pad (not illustrated) provided in the transistor 10. The gate resistor 16 has a function of adjusting the transmission time of a gate voltage to control the switching speed of the transistor 10 or to control an overshoot voltage and an overshoot current.

The voltage detector 22 has a function of detecting a change in the gate voltage (first gate voltage) applied to the gate electrode 10c over time. The voltage detector 22 detects, for example, the voltage between the gate resistor 16 and the gate electrode 10c. The voltage detector 22 has a function of acquiring the waveform of the gate voltage applied to the gate electrode 10c.

The gate electrode 10c is an example of the first gate electrode. The gate voltage applied to the gate electrode 10c is an example of a first parameter of the transistor 10. The waveform of the gate voltage applied to the gate electrode 10c is an example of first temporal change data.

For example, a known voltage detection circuit can be used as the voltage detector 22. The voltage detector 22 acquires the waveform of the gate voltage as analog data.

The analog-digital convertor 24 has a function of converting the waveform of the gate voltage acquired by the voltage detector 22 from analog data to digital data. The analog-digital convertor 24 is, for example, a known analog-digital conversion circuit.

The first storage 26 has a function of storing the waveform of the gate voltage converted into the digital data by the analog-digital convertor 24. The first storage 26 is, for example, a non-volatile semiconductor memory.

The interface 28 has a function of enabling an external device to read the waveform of the gate voltage stored in the first storage 26. The interface 28 is, for example, a known interface circuit.

The interface 28 is provided with, for example, an output terminal and a control terminal. In a case in which a control signal is input to the control terminal, the waveform of the gate voltage stored in the first storage 26 is output from the output terminal.

Next, the function and effect of the semiconductor device and the power convertor according to the first embodiment will be described.

For example, in some cases, the power transistor included in the power convertor is broken while the power convertor is operating. For example, it is considered that the destruction of the power transistor is caused by some factors, such as a surge voltage during a turn-off operation and a short circuit caused by erroneous ignition.

In a case in which the power transistor is broken, it is difficult to determine the cause of the destruction after the fact. It is preferable to easily determine the cause of the destruction of the power transistor in order to clarify the cause of the destruction of the power transistor and to achieve a high-reliability power convertor.

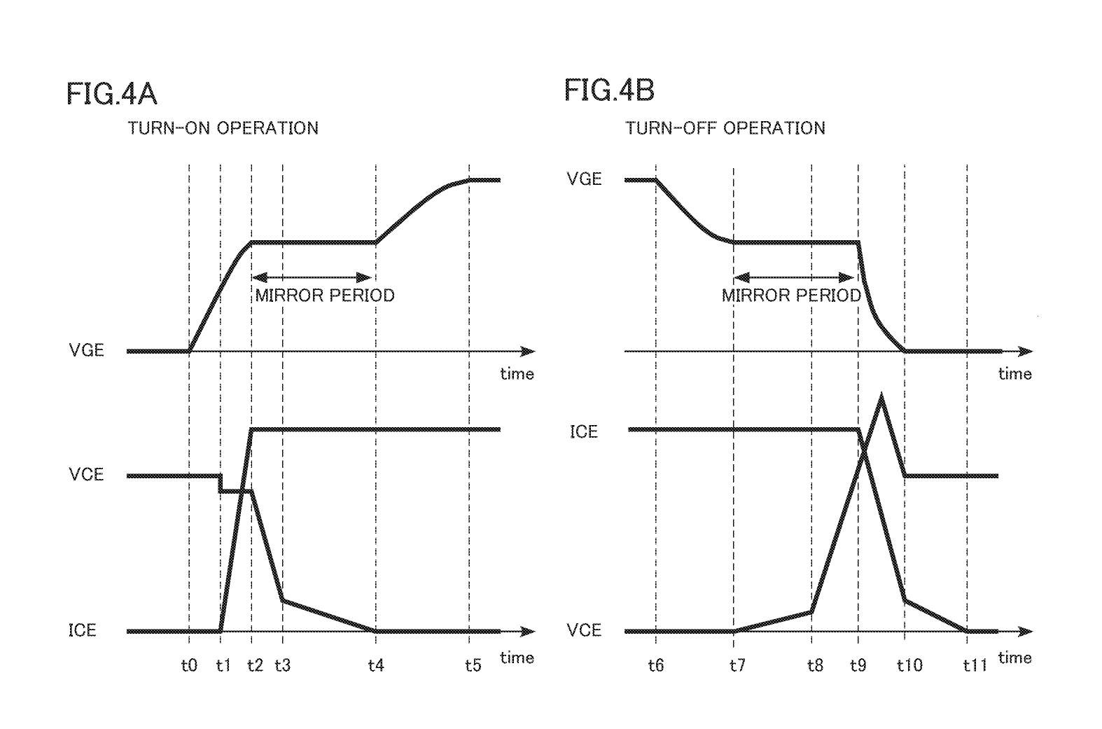

FIGS. 4A and 4B are diagrams illustrating the function and effect of the semiconductor device according to the first embodiment. FIGS. 4A and 4B illustrate a change in a gate voltage VGE, a collector-emitter voltage VCE, and a collector-emitter current ICE over time during a switching operation of the transistor 10. FIGS. 4A and 4B illustrate the waveforms of the gate voltage VGE, the collector-emitter voltage VGE and the collector-emitter current ICE during the switching operation of the transistor 10. FIG. 4A illustrates the waveform of the turn-on operation and FIG. 4B illustrates the waveform of the turn-off operation.

The transistor circuit 100 according to the first embodiment stores the waveform of the gate voltage (corresponding to VGE in FIGS. 4A and 4B) applied to the gate electrode 10c of the transistor 10. In a case in which the transistor 10 is broken and the inverter circuit 110 operates abnormally, the waveform of the gate voltage VGE stored in the first storage 26 is read through the interface 28. The waveform of the gate voltage VGE when the transistor 10 is broken can be checked, which makes it possible to easily determine the cause of the destruction of the transistor 10.

For example, in a case in which the read waveform of the gate voltage VGE clearly shows that the transistor 10 has been broken for the period from t9 to t10 in FIG. 4B, it can be presumed that VCE is equal to or higher than the limit due to a surge voltage during the turn-off operation, which results in the destruction of the transistor 10.

For example, in a case in which the gate voltage VGE is clearly higher than a threshold voltage before a time t0 or after a time t11 when the gate voltage VGE is 0 V in a normal state, it can be presumed that the transistor 10 has been broken due to a short circuit caused by erroneous ignition.

It is known that the gate voltage VGE for a mirror period of the transistor 10 is correlated with the collector-emitter current ICE. Therefore, for example, in a case in which the gate voltage VGE for the mirror period when the transistor 10 is broken is equal to or greater than an assumed value, it can be presumed that a large amount of collector-emitter current ICE flows, which results in the destruction of the transistor 10.

It is preferable that the first storage 26 store at least the waveform of the gate voltage VGE corresponding to one cycle from the turn-on operation to the turn-off operation. The storage of the waveform of the gate voltage VGE corresponding to one cycle makes it easy to determine the cause of the destruction of the transistor 10.

### MODIFICATION EXAMPLE

A modification example of the first embodiment includes a current detector instead of the voltage detector 22. The current detector is an example of the first detector. The current detector has a function of detecting a change in a gate current flowing to the gate electrode 10c over time. The current detector detects, for example, a current flowing between the gate resistor 16 and the gate electrode 10c. The current detector has a function of acquiring the waveform of the gate current flowing to the gate electrode 10c.

As described above, according to the first embodiment, it is possible to easily determine the cause of the destruction of the transistor 10 included in the transistor circuit 100 or the inverter circuit 110.

### SECOND EMBODIMENT

A semiconductor device and a power convertor according to a second embodiment differ from those according to the first embodiment in that the first parameter is a current flowing to the transistor. Hereinafter, the description of a portion of the same content as that in the first embodiment will not be repeated.

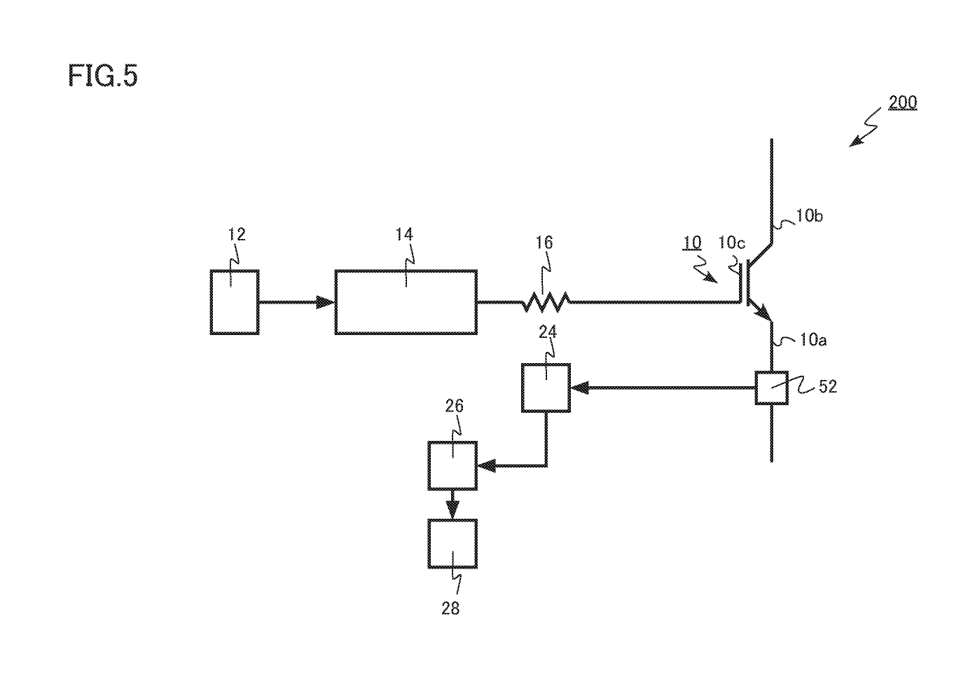

FIG. 5 is a diagram schematically illustrating the semiconductor device according to the second embodiment. The semiconductor device according to the second embodiment is a transistor circuit 200. The transistor circuit 200 is a portion of the inverter circuit 110.

The transistor circuit 200 includes a transistor 10, a gate pulse generation circuit 12, a gate driving circuit 14, a gate resistor 16, a current detector 52 (first detector), an analog-digital convertor 24, a first storage 26, and an interface 28.

The current detector 52 has a function of detecting a change in a current flowing between a collector electrode 10b and an emitter electrode 10a over time. The current detector 52 has a function of acquiring the waveform of a collector-emitter current flowing between the collector electrode 10b and the emitter electrode 10a.

The collector-emitter current flowing between the collector electrode 10b and the emitter electrode 10a is an example of the first parameter. The waveform of the collector-emitter current is an example of the first temporal change data.

For example, a known current detection circuit can be used as the current detector 52. The current detector 52 acquires the waveform of the collector-emitter current as analog data.

The analog-digital convertor 24 has a function of converting the waveform of the collector-emitter current acquired by the current detector 52 from analog data to digital data.

The first storage 26 has a function of storing the waveform of the collector-emitter current converted into the digital data by the analog-digital convertor 24.

The interface 28 has a function of enabling an external device to read the waveform of the collector-emitter current stored in the first storage 26.

The waveform of the collector-emitter current stored in the first storage 26 corresponds to the waveform of the collector-emitter current ICE illustrated in FIGS. 4A and 4B.

In a case in which the transistor 10 is broken and the inverter circuit 110 operates abnormally, the waveform of the collector-emitter current ICE stored in the first storage 26 is read through the interface 28. The waveform of the collector-emitter current ICE when the transistor 10 is broken can be checked, which makes it possible to easily determine the cause of the destruction of the transistor 10.

As described above, according to the second embodiment, it is possible to easily determine the cause of the destruction of the transistor 10 included in the transistor circuit 200 or the inverter circuit 110.

### THIRD EMBODIMENT

A semiconductor device and a power convertor according to a third embodiment differ from those according to the first embodiment in that they further include a second detector detecting a change in a second parameter of the transistor over time to acquire second temporal change data and a second storage storing the second temporal change data and the second parameter is a current flowing to the transistor. Hereinafter, the description of a portion of the same content as that in the first embodiment will not be repeated.

The semiconductor device according to the third embodiment is a combination of the semiconductor device according to the first embodiment and the semiconductor device according to the second embodiment.

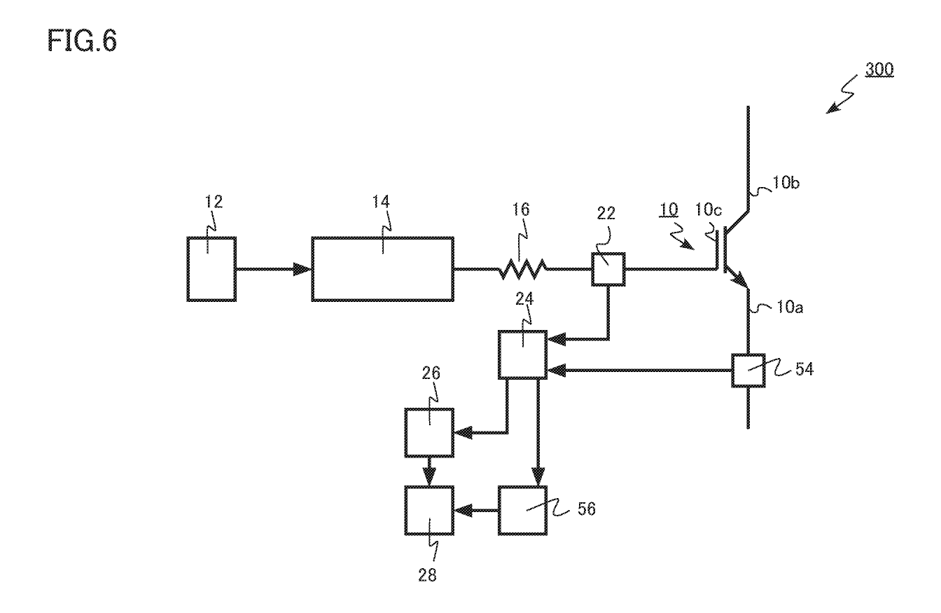

FIG. 6 is a diagram schematically illustrating the semiconductor device according to the third embodiment. The semiconductor device according to the third embodiment is a transistor circuit 300. The transistor circuit 300 is a portion of the inverter circuit 110.

The transistor circuit 300 includes a transistor 10, a gate pulse generation circuit 12, a gate driving circuit 14, a gate resistor 16, a voltage detector 22 (first detector), a current detector 54 (second detector), an analog-digital convertor 24, a first storage 26, a second storage 56, and an interface 28.

The current detector 54 has a function of detecting a change in a current flowing between a collector electrode 10b and an emitter electrode 10a over time. The current detector 54 has a function of acquiring the waveform of a collector-emitter current flowing between the collector electrode 10b and the emitter electrode 10a. The current detector 54 is an example of the second detector.

The collector-emitter current flowing between the collector electrode 10b and the emitter electrode 10a is an example of the second parameter. The waveform of the collector-emitter current is an example of the second temporal change data.

For example, a known current detection circuit can be used as the current detector 54. The current detector 54 acquires the waveform of the collector-emitter current as analog data.

The analog-digital convertor 24 has a function of converting the waveform of the gate voltage acquired by the voltage detector 22 from analog data to digital data. In addition, the analog-digital convertor 24 has a function of converting the waveform of the collector-emitter current acquired by the current detector 54 from analog data to digital data.

The second storage 56 has a function of storing the waveform of the collector-emitter current converted into the digital data by the analog-digital convertor 24. The second storage 56 is, for example, a non-volatile semiconductor memory. In addition, the first storage 26 and the second storage 56 may be, for example, the same non-volatile semiconductor memory.

The interface 28 has a function of enabling an external device to read the waveform of the gate voltage stored in the first storage 26 and the waveform of the collector-emitter current stored in the second storage 56.

The waveform of the collector-emitter current stored in the second storage 56 corresponds to the waveform of the collector-emitter current ICE illustrated in FIGS. 4A and 4B.

In a case in which the transistor 10 is broken and the inverter circuit 110 operates abnormally, the waveform of the gate voltage VGE stored in the first storage 26 is read through the interface 28. In addition, the waveform of the collector-emitter current ICE stored in the second storage 56 is read through the interface 28. Both the waveform of the gate voltage VGE and the waveform of the collector-emitter current ICE when the transistor 10 is broken can be checked, which makes it possible to easily determine the cause of the destruction of the transistor 10.

As described above, according to the third embodiment, it is possible to further easily determine the cause of the destruction of the transistor 10 included in the transistor circuit 300 or the inverter circuit 110.

### FOURTH EMBODIMENT

A semiconductor device and a power convertor according to a fourth embodiment differ from those according to the first embodiment in that they further include a standard data storage storing standard temporal change data of the first parameter, a comparator comparing the standard temporal change data with the first temporal change data, and a protective circuit stopping the operation of the transistor on the basis of the comparison result of the comparator. Hereinafter, the description of a portion of the same content as that in the first embodiment will not be repeated.

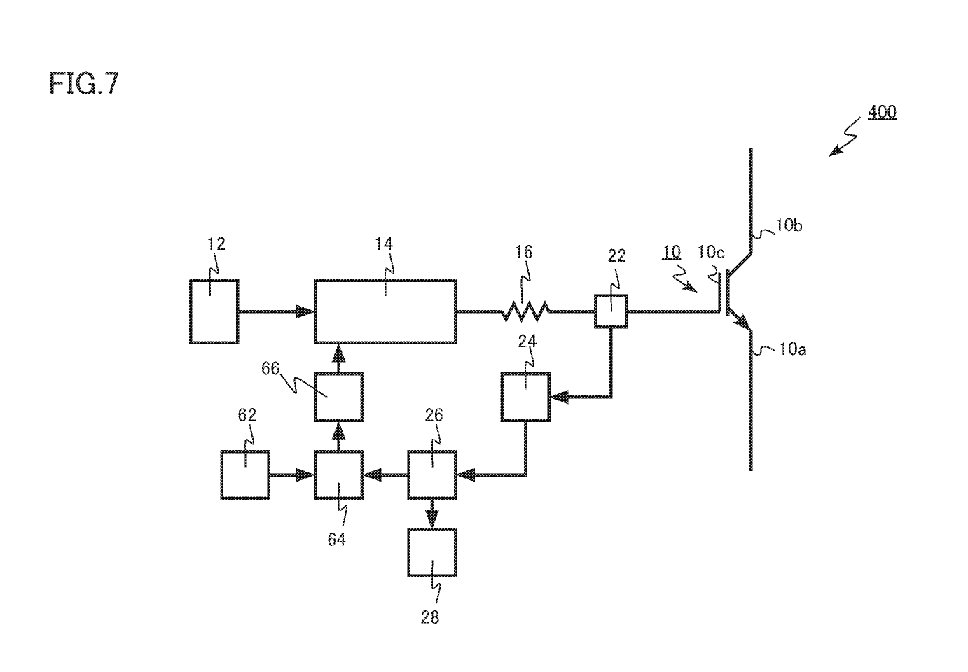

FIG. 7 is a diagram schematically illustrating the semiconductor device according to the fourth embodiment. The semiconductor device according to the fourth embodiment is a transistor circuit 400. The transistor circuit 400 is a portion of the inverter circuit 110.

The transistor circuit 400 includes a transistor 10, a gate pulse generation circuit 12, a gate driving circuit 14, a gate resistor 16, a voltage detector 22 (first detector), an analog-digital convertor 24, a first storage 26, an interface 28, a standard data storage 62, a comparator 64, and a protective circuit 66.

The standard data storage 62 has a function of storing a standard waveform of the gate voltage. The standard waveform is the waveform of the gate voltage in a case in which the transistor 10 operates normally. The gate voltage is an example of the first parameter. The standard waveform of the gate voltage is an example of the standard temporal change data.

The standard data storage 62 is, for example, a non-volatile semiconductor memory. The first storage 26 and the standard data storage 62 may be, for example, the same non-volatile semiconductor memory.

The comparator 64 has a function of comparing the waveform of the gate voltage stored in the first storage 26 with the standard waveform of the gate voltage stored in the standard data store 62. For example, the comparator 64 has a function of calculating a difference between the waveform of the gate voltage stored in the first storage 26 and the standard waveform.

The comparator 64 is, for example, a logic circuit. The comparator 64 may be, for example, a microcomputer or an analog circuit.

The protective circuit 66 has a function of stopping the operation of the transistor on the basis of the comparison result between the waveform of the gate voltage and the standard waveform by the comparator 64. For example, in a case in which the difference between the waveform of the gate voltage and the standard waveform is greater than a predetermined value, the protective circuit 66 transmits a control signal to the gate driving circuit 14 to stop the operation of the transistor 10.

The protective circuit 66 is, for example, a logic circuit. The protective circuit 66 may be, for example, a microcomputer or an analog circuit. The protective circuit 66 may be, for example, the same microcomputer as the comparator 64.

According to the transistor circuit 400, it is possible to prevent the destruction of the transistor 10.

As described above, according to the fourth embodiment, similarly to the first embodiment, it is possible to easily determine the cause of the destruction of the transistor 10 included in the transistor circuit 400 or the inverter circuit 110. In addition, it is possible to prevent the destruction of the transistor 10.

### FIFTH EMBODIMENT

A semiconductor device and a power convertor according to a fifth embodiment differ from those according to the first embodiment in that the first parameter is the temperature of the transistor. Hereinafter, the description of a portion of the same content as that in the first embodiment will not be repeated.

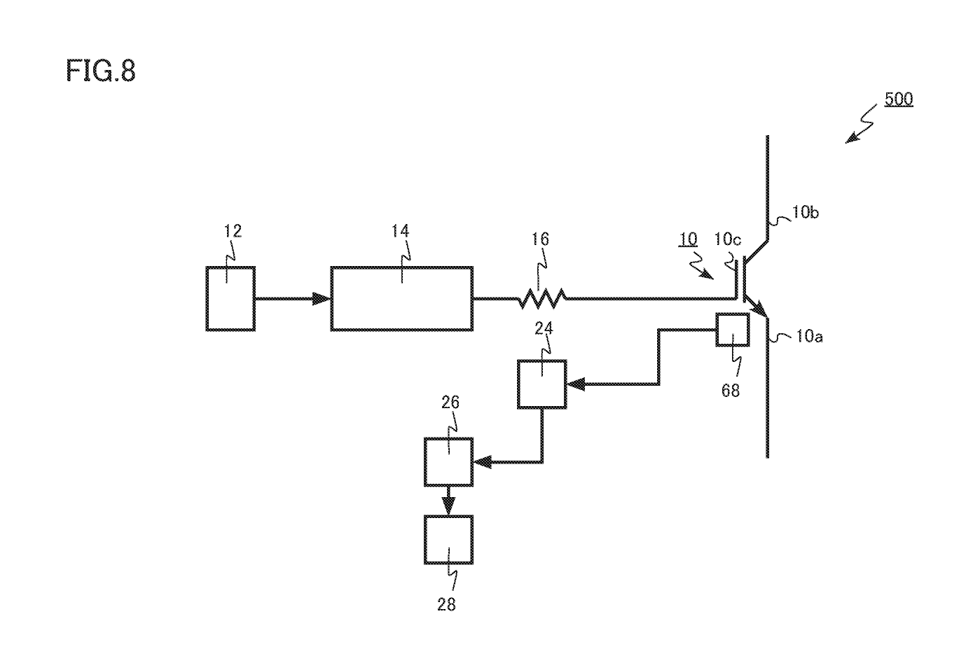

FIG. 8 is a diagram schematically illustrating the semiconductor device according to the fifth embodiment. The semiconductor device according to the fifth embodiment is a transistor circuit 500. The transistor circuit 500 is a portion of the inverter circuit 110.

The transistor circuit 500 includes a transistor 10, a gate pulse generation circuit 12, a gate driving circuit 14, a gate resistor 16, a temperature detector 68 (first detector), an analog-digital convertor 24, a first storage 26, and an interface 28.

The temperature detector 68 is provided in the vicinity of the transistor 10. The temperature detector 68 has a function of detecting the temperature of the transistor 110. The temperature detector 68 has a function of acquiring a change in the temperature of the transistor 10 over time.

The temperature of the transistor 10 is an example of the first parameter. The change in the temperature of the transistor 10 over time is an example of the first temporal change data.

For example, a temperature sensor using a diode or a thermocouple can be used as the temperature detector 68.

The analog-digital convertor 24 has a function of converting the change in the temperature over time acquired by the temperature detector 68 from analog data to digital data.

The first storage 26 has a function of storing the change in the temperature over time which has been converted into the digital data by the analog-digital convertor 24.

The interface 28 has a function of enabling an external device to read the change in the temperature over time stored in the first storage 26.

In a case in which the transistor 10 is broken and the inverter circuit 110 operates abnormally, the change in the temperature over time stored in the first storage 26 is read through the interface 26. The change in the temperature over time when the transistor 10 is broken can be checked, which makes it possible to easily determine the cause of the destruction of the transistor 10.

As described above, according to the fifth embodiment, it is possible to easily determine the cause of the destruction of the transistor 10 included in the transistor circuit 500 or the inverter circuit 110.

### SIXTH EMBODIMENT

A semiconductor device and a power convertor according to a sixth embodiment differ from those according to the first embodiment in that they further include a gate timing control circuit, the transistor has a second gate electrode to which a second gate voltage is applied, and the gate timing control circuit controls the time when the first gate voltage is applied and the time when the second gate voltage is applied on the basis of the first temporal change data stored in the first storage. Hereinafter, the description of a portion of the same content as that in the first embodiment will not be repeated.

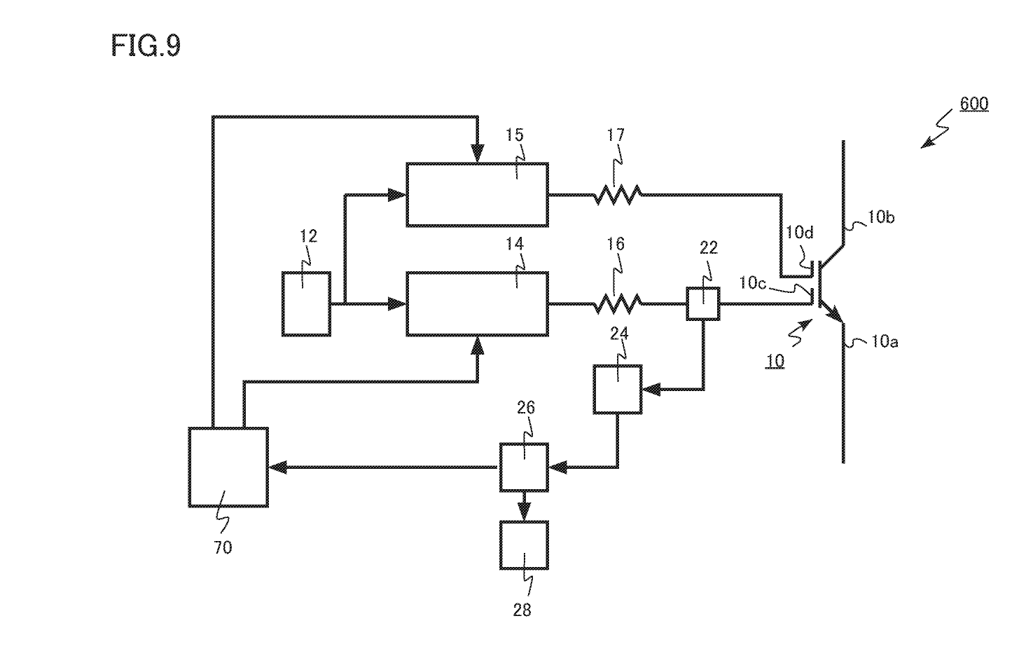

FIG. 9 is a diagram schematically illustrating the semiconductor device according to the sixth embodiment. The semiconductor device according to the sixth embodiment is a transistor circuit 600. The transistor circuit 600 is a portion of the inverter circuit 110.

The transistor circuit 600 includes a transistor 10, a gate pulse generation circuit 12, a gate driving circuit 14, a gate driving circuit 15, a gate resistor 16, a gate resistor 17, a voltage detector 22 (first detector), an analog-digital convertor 24, a first storage 26, an interface 28, and a gate timing control circuit 70.

The transistor 10 includes an emitter electrode 10a (first electrode), a collector electrode 10b (second electrode), a gate electrode 10c (first gate electrode), and a gate electrode 10d (second gate electrode).

The transistor 10 is a vertical insulated gate bipolar transistor (IGBT). The transistor 10 has a double gate structure having two gate electrodes that are separately driven.

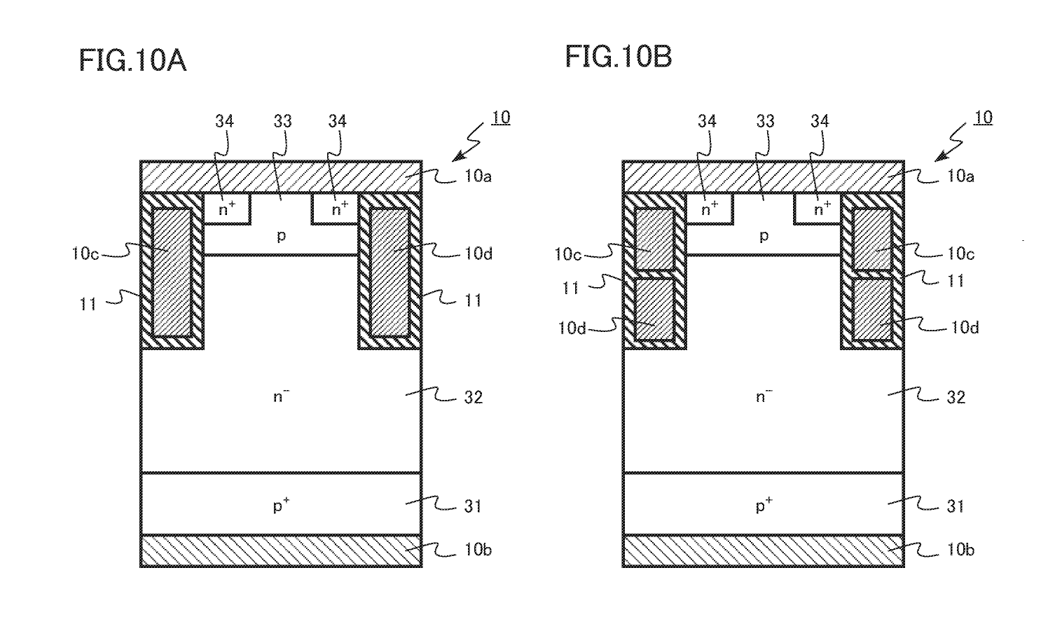

FIGS. 10A and 10B are cross-sectional views schematically illustrating the transistor 10 according to the sixth embodiment. The transistor 10 includes the emitter electrode 10a, the collector electrode 10b, the gate electrode 10c, the gate electrode 10d, a gate insulating film 11, a p⁺ collector region 31, an n⁻ drift region 32, a p-type base region 33, and an n⁺ emitter region 34. The p⁺ collector region 31, the n⁻ drift region 32, the p-type base region 33, and the n⁺ emitter region 34 are formed in, for example, a single-crystal silicon layer or a single-crystal silicon carbide layer.

In the transistor 10 illustrated in FIG. 10A, adjacent gate electrodes are the gate electrode 10c and the gate electrode 10d. In the transistor 10 illustrated in FIG. 10B, the gate electrode 10c and the gate electrode 10d are disposed in the vertical direction.

In the transistor 10 having the double gate structure, the switching time of two gate electrodes is changed to achieve desired transistor characteristics. For example, the switching time of two gate electrodes can be changed to achieve a transistor with low switching loss.

The gate driving circuit 14 has a function of generating the gate voltage to be applied to the gate electrode 10c on the basis of a gate signal to control the driving of the transistor 10.

The gate resistor 16 is provided between the gate driving circuit 14 and the gate electrode 10c. The gate resistor 16 has a function of adjusting the transmission time of the gate voltage to control the switching speed of the transistor 10.

The gate driving circuit 15 has a function of generating the gate voltage to be applied to the gate electrode 10d on the basis of a gate signal to control the driving of the transistor 10.

The gate resistor 17 is provided between the gate driving circuit 15 and the gate electrode 10d. The gate resistor 17 has a function of adjusting the transmission time of the gate voltage to control the switching speed of the transistor 10.

The gate timing control circuit 70 controls the time when the gate voltage is applied to the gate electrode 10c and the time when the gate voltage is applied to the gate electrode 10d on the basis of the waveform of the gate voltage applied to the gate electrode 10c stored in the first storage 26. For example, the gate timing control circuit 70 transmits a control signal to the gate driving circuit 14 and the gate driving circuit 15 to change the time when the gate voltage is applied to the gate electrode 10c and the time when the gate voltage is applied to the gate electrode 10d.

The gate voltage applied to the gate electrode 10c is an example of the first parameter of the transistor 10. The waveform of the gate voltage applied to the gate electrode 10c is an example of the first temporal change data.

In the transistor 10 having the double gate structure, for example, it is preferable to change the switching time of two gate electrodes depending on the collector-emitter current ICE of the transistor 10.

It is known that the gate voltage VGE for the mirror period of the transistor 10 is correlated with the collector-emitter current ICE. Therefore, the gate voltage VGE is an index of the size of the collector-emitter current ICE.

According to the transistor circuit 600, the time when the gate voltage is applied to the gate electrode 10c and the time when the gate voltage is applied to the gate electrode 10d are controlled on the basis of the waveform of the gate voltage applied to the gate electrode 10c. Therefore, it is possible to control the switching time of two gate electrodes according to the collector-emitter current ICE. As a result, it is possible to improve the characteristics of the transistor 10 and the characteristics of the transistor circuit 600.

As described above, according to the sixth embodiment, similarly to the first embodiment, it is possible to easily determine the cause of the destruction of the transistor 10 included in the transistor circuit 600 or the inverter circuit 110. In addition, it is possible to improve the characteristics of the transistor circuit 600.

### SEVENTH EMBODIMENT

In a semiconductor device according to a seventh embodiment, the transistor, the first detector, and the first storage according to the first embodiment are provided on the same semiconductor substrate. Hereinafter, the description of a portion of the same content as that in the first embodiment will not be repeated.

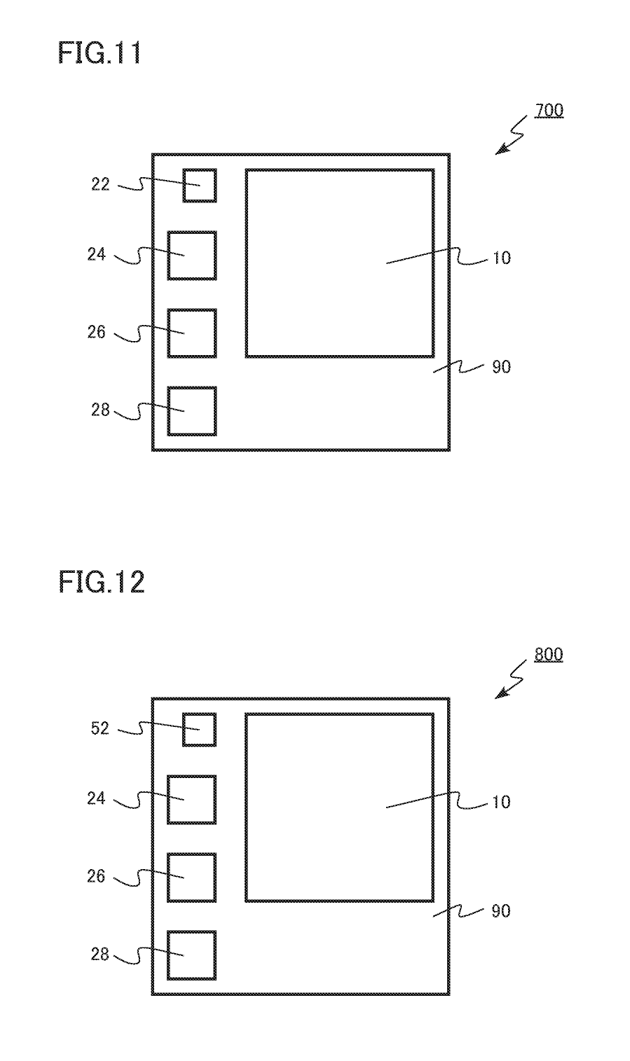

FIG. 11 is a diagram schematically illustrating the semiconductor device according to the seventh embodiment. The semiconductor device according to the seventh embodiment is a semiconductor chip 700.

The semiconductor chip 700 includes a semiconductor substrate 90, a transistor 10, a voltage detector 22 (first detector), an analog-digital convertor 24, a first storage 26, and an interface 28.

The transistor 10, the voltage detector 22, the analog-digital convertor 24, the first storage 26, and the interface 28 are formed on the same semiconductor substrate 90. The transistor 10, the voltage detector 22, the analog-digital convertor 24, the first storage 26, and the interface 28 are integrated into one chip.

All of the transistor 10, the voltage detector 22, the analog-digital convertor 24, the first storage 26, and the interface 28 may be formed in the same semiconductor layer. In addition, any of the transistor 10, the voltage detector 22, the analog-digital convertor 24, the first storage 26, and the interface 28 may be formed in different semiconductor layers.

As described above, according to the seventh embodiment, it is possible to easily determine the cause of the destruction of the transistor 10 included in the semiconductor chip 700.

### EIGHTH EMBODIMENT

In a semiconductor device according to an eighth embodiment, the transistor, the first detector, and the first storage according to the second embodiment are provided on the same semiconductor substrate. Hereinafter, the description of a portion of the same content as that in the second embodiment will not be repeated.

FIG. 12 is a diagram schematically illustrating the semiconductor device according to the eighth embodiment. The semiconductor device according to the eighth embodiment is a semiconductor chip 800.

The semiconductor chip 800 includes a semiconductor substrate 90, a transistor 10, a current detector 52 (first detector), an analog-digital convertor 24, a first storage 26, and an interface 28.

The transistor 10, the current detector 52, the analog-digital convertor 24, the first storage 26, and the interface 28 are formed on the same semiconductor substrate 90. The transistor 10, the current detector 52, the analog digital convertor 24, the first storage 26, and the interface 28 are integrated into one chip.

All of the transistor 10, the current detector 52, the analog-digital convertor 24, the first storage 26, and the interface 28 may be formed in the semiconductor layer. Any of the transistor 10, the current detector 52, the analog-digital convertor 24, the first storage 26, and the interface 28 may be formed in different semiconductor layers.

As described above, according to the eighth embodiment, it is possible to easily determine the cause of the destruction of the transistor 10 included in the semiconductor chip 800.

### NINTH EMBODIMENT

In a semiconductor device according to a ninth embodiment, the transistor, the first detector, the first storage, the second detector, and the second storage according to the third embodiment are provided on the same semiconductor substrate. Hereinafter, the description of a portion of the same content as that in the third embodiment will not be repeated.

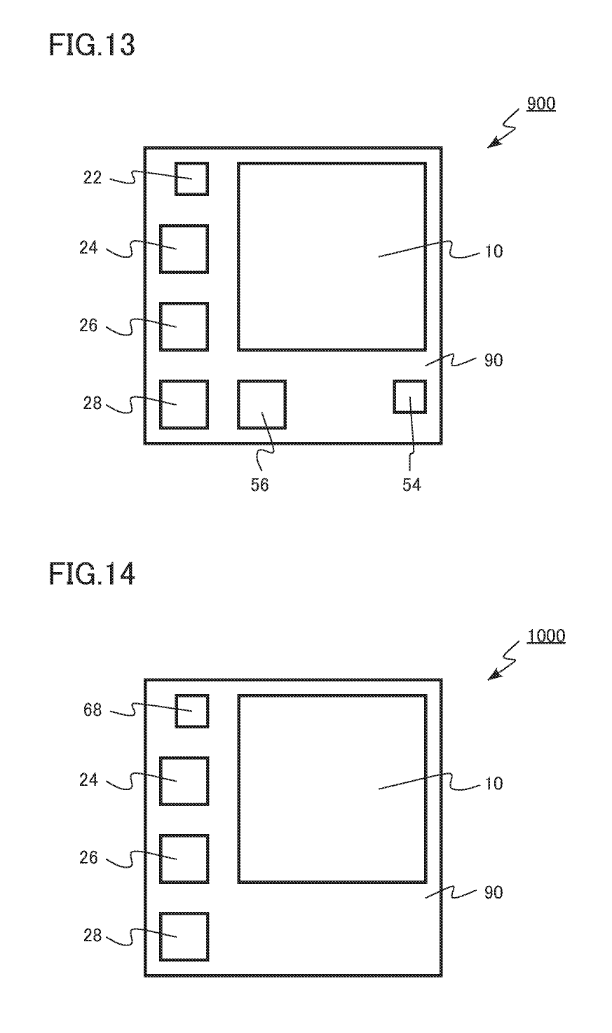

FIG. 13 is a diagram schematically illustrating the semiconductor device according to the ninth embodiment. The semiconductor device according to the ninth embodiment is a semiconductor chip 900.

The semiconductor chip 900 includes a semiconductor substrate 90, a transistor 10, a voltage detector 22 (first detector), a current detector 54 (second detector), an analog-digital convertor 24, a first storage 26, a second storage 56, and an interface 28.

The transistor 10, the voltage detector 22, the current detector 54, the analog-digital convertor 24, the first storage 26, the second storage 56, and the interface 28 are formed on the same semiconductor substrate 90. The transistor 10, the voltage detector 22, the current detector 54, the analog-digital convertor 24, the first storage 26, the second storage 56, and the interface 28 are integrated into one chip.

All of the transistor 10, the voltage detector 22, the current detector 54, the analog-digital convertor 24, the first storage 26, the second storage 56, and the interface 28 may be formed in the same semiconductor layer. In addition, any of the transistor 10, the voltage detector 22, the current detector 54, the analog-digital convertor 24, the first storage 26, the second storage 56, and the interface 28 may be formed in different semiconductor layers.

As described above, according to the ninth embodiment, it is possible to easily determine the cause of the destruction of the transistor 10 included in the semiconductor chip 900.

### TENTH EMBODIMENT

In a semiconductor device according to a tenth embodiment, the transistor, the first detector, and the first storage according to the fifth embodiment are provided on the same semiconductor substrate. Hereinafter, the description of a portion of the same content as that in the fifth embodiment will not be repeated.

FIG. 14 is a diagram schematically illustrating the semiconductor device according to the tenth embodiment. The semiconductor device according to the tenth embodiment is a semiconductor chip 1000.

The semiconductor chip 1000 includes a semiconductor substrate 90, a transistor 10, a temperature detector 68 (first detector), an analog-digital convertor 24, a first storage 26, and an interface 28.

The transistor 10, the temperature detector 68 (first detector), the analog-digital convertor 24, the first storage 26, and the interface 28 are formed on the same semiconductor substrate 90. The transistor 10, the temperature detector 68, the analog-digital convertor 24, the first storage 26, and the interface 28 are integrated into one chip.

All of the transistor 10, the temperature detector 68, the analog-digital convertor 24, the first storage 26, and the interface 28 may be formed in the same semiconductor layer. In addition, any of the transistor 10, the temperature detector 68, the analog-digital convertor 24, the first storage 26, and the interface 28 may be formed in different semiconductor layers.

As described above, according to the tenth embodiment, it is possible to easily determine the cause of the destruction of the transistor 10 included in the semiconductor chip 1000.

In the first to sixth embodiments, the inverter circuit has been described as an example of the power convertor. However, a DC-DC converter may be applied as the power convertor. In addition, a case in which the transistor of the power convertor is controlled has been described as an example. However, the invention may be applied to transistors other than the transistor used in the power convertor.

In the first to tenth embodiments, the IGBT has been described as an example of the transistor. However, the transistor is not necessarily limited to the IGBT. For example, other transistors, such as a metal oxide field effect transistor (MOSFET) and a high electron mobility transistor (HEMT), may be applied.

While certain embodiments have been described, these embodiments have been presented by way of example only, and are not intended to limit the scope of the inventions. Indeed, the semiconductor devices and the power convertors described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

1. A semiconductor device comprising:
a transistor including a first electrode, a second electrode, and a first gate electrode;
a first detector detecting a change in a first parameter of the transistor over time to acquire first temporal change data;
a first storage storing the first temporal change data;
a gate driving circuit controlling the first gate voltage applied to the first gate electrode; and
a gate resistor provided between the gate driving circuit and the first gate electrode,
wherein the first parameter is a first gate voltage applied to the first gate electrode, and the first detector detects a change in the first gate voltage between the gate resistor and the first gate electrode over time.

2. The semiconductor device according to claim 1, further comprising:
an analog-digital convertor converting the first temporal change data into digital data before the first temporal change data is stored in the first storage.

3. The semiconductor device according to claim 1, further comprising:
an interface enabling an external device to read the first temporal change data stored in the first storage.

4. (canceled)

5. (canceled)

6. The semiconductor device according to claim 1, further comprising:
a second detector detecting a change in a second parameter of the transistor over time to acquire second temporal change data; and
a second storage storing the second temporal change data,
wherein the second parameter is a current flowing to the transistor.

7. The semiconductor device according to claim 1, further comprising:
a standard data storage storing standard temporal change data of the first parameter;
a comparator comparing the standard temporal change data with the first temporal change data; and
a protective circuit stopping an operation of the transistor on the basis of a comparison result of the comparator.

8-10. (canceled)

11. A semiconductor device comprising:
a transistor including a first electrode, a second electrode, and a first gate electrode;
a first detector detecting a change in a first parameter of the transistor over time to acquire first temporal change data;
a first storage storing the first temporal change data; and
a gate timing control circuit,
wherein the first parameter is a first gate voltage applied to the first gate electrode,
the transistor includes a second gate electrode,
a second gate voltage is applied to the second gate electrode,
the gate timing control circuit controls a time when the first gate voltage is applied and a time when the second gate voltage is applied, on the basis of the first temporal change data stored in the first storage.

12. The semiconductor device according to claim 1,
wherein the first storage is a non-volatile semiconductor memory.

13. The semiconductor device according to claim 1,
wherein the transistor, the first detector, and the first storage are provided on the same semiconductor substrate.

14. The semiconductor device according to claim 6,
wherein the transistor, the first detector, the first storage, the second detector, and the second storage are provided on the same semiconductor substrate.

15. A power convertor comprising the semiconductor device according to claim 1.
